(19) United States
(12) Patent Application Publication
(10) Pub. No.: US 2010/0207120 A1
(43) Pub. Date: Aug. 19, 2010

(54) PRODUCTION METHOD OF SEMICONDUCTOR DEVICE AND SEMICONDUCTOR DEVICE

(75) Inventors: Tomohiro Kimura, Osaka (JP); Shigeyasu Mori, Osaka (JP)

Correspondence Address: BIRCH STEWART KOLASCH & BIRCH, PO BOX 747, FALLS CHURCH, VA, 22040-0747, US

(73) Assignee: SHARP KABUSHIKI KAISHA, Osaka-shi, Osaka (JP)

(21) Appl. No.: 12/676,945

(22) PCT Filed: May 23, 2008
(86) PCT No.: PCT/JP2008/059559

§ 371 Date: Mar. 8, 2010

(30) Foreign Application Priority Data
Sep. 18, 2007 (JP) 2007-241052

(51) Int. Cl. H01L 29/786; H01L 21/336

(52) U.S. Cl. 257/57; 438/151; 257/66

(57) ABSTRACT

The present invention provides a production method of a semiconductor device and a semiconductor device that permits suppression of a leakage current. A production method of a semiconductor device includes a structure in which a semiconductor layer, an insulating film, and a gate electrode are stacked on a main surface of a substrate in this order,
the method comprises an impurity-adding step of:
adding impurities to at least a portion of the semiconductor layer, the portion facing the gate electrode, so that a portion of the semiconductor layer, the portion being an edge region and facing the gate electrode, has an impurity concentration greater than an impurity concentration of a portion of the semiconductor layer, the portion being a non-edge region and facing the gate electrode.

### TECHNICAL FIELD

The present invention relates to a production method of a semiconductor device and a semiconductor device. More particularly, the present invention relates to a production method of a semiconductor device and a semiconductor device preferably used in a display device such as an LCD device.

### BACKGROUND ART

Semiconductor devices are active element-including electronic devices using electrical characteristics of a semiconductor. Such semiconductor devices have been widely applied to audio-visual apparatuses, communication facilities, computers, and electrical household appliances. Among these, a TFT (thin film transistor)-including semiconductor device is widely applied to a pixel switching element, a driver circuit, and the like, in an active matrix LCD device.

A configuration of a conventional TFT is described. FIG. 12 is a schematic view showing a configuration of a conventional TFT. FIG. 12(a) is a plan view thereof. FIG. 12(b) is a sectional view taken along line Y3-Y4 in FIG. 12(a). FIG. 12(c) is a sectional view taken along line X3-X4 in FIG. 12(a).

The conventional TFT 110 includes, as shown in FIG. 12, a structure in which a base layer 117, an island-shaped semiconductor layer 120, an insulating film 112, and a gate electrode 114 are stacked on a substrate 111 in this order. The TFT 110 further includes an interlayer insulating film 115 covering the above-mentioned components and wirings 116a and 116b formed on the interlayer insulating film 115. The semiconductor layer 120 has a channel region 121 facing the gate electrode 114 and source-drain regions 122 formed in a region except for the channel region 121. The wirings 116a and 116b are connected to the source-drain regions 122 through contact holes 118a and 118b, respectively.

A technology of permitting high speed operation of the conventional TFT 110 by crystallizing the semiconductor layer 120, thereby improving mobility, is being researched and developed.

For example, Patent Document 1 discloses the following production method of a semiconductor device as a technology of a conventional semiconductor device. First and second semiconductor layers are formed on a base insulating film, and thereon, an insulating film is further formed. The insulating film that is positioned on a channel-forming region of the first semiconductor layer is removed by etching using the first semiconductor layer as an etching stopper. This method can prevent spot-facing in the base insulating film that is below the semiconductor layers.

### [Patent Document 1]

Japanese Kokai Publication No. 2005-183774

### DISCLOSURE OF INVENTION

However, the conventional TFT 110, particularly the TFT 110 including a crystalline semiconductor layer, may have large current leakage in an OFF-state, that is, a large leakage current. Referring to FIG. 13, the reason why the large leakage current is generated in the conventional TFT 110 is described below. FIG. 13 is a conceptual view showing gate voltage-drain current characteristics of the conventional TFT. In FIG. 13, the thick curve shows transistor characteristics of the whole conventional TFT 110. The thick dotted curve shows transistor characteristics of a channel edge region, described below, and the thin dotted curve shows transistor characteristics of a channel body region, described below. As shown in the thick curve in FIG. 13, in the curve showing gate voltage (Vg)-drain current (Id) characteristics of the conventional TFT 110, a bump (shoulder) 150 may be generated at about a threshold voltage (Vth) where a drain current rises. Accordingly, a circuit including the conventional TFT 110 needs to be designed to have a large voltage difference between in an on-state and in an off-state. This may cause a trouble in circuit driving at a low voltage. In order to suppress the generation of the bump in the Vg-Id characteristics curve (hereinafter, also referred to as simply “bump”), the circuit including the conventional TFT 110 needs to be designed so that the TFT 110 has a high Vth. Therefore, a circuit driving voltage rises, which causes an increase in a load on the circuit and an increase in power consumption.

The present invention has been made in view of the above-mentioned state of the art. The present invention has an object to provide a production method of a semiconductor device and a semiconductor device that permits suppression of a leakage current.

The present inventors made various investigations on a production method of a semiconductor device and a semiconductor device that permits suppression of a leakage current. The inventors noted a concentration of impurities added into a semiconductor layer. The inventors found that, in the conventional TFT, the bump is generated in the Vg-Id characteristics curve because impurities are added to a channel region to have a uniform concentration for adjustment of Vth. The inventors also found that the generation of the bump can be suppressed by adding impurities to at least a portion of the semiconductor layer, the portion facing the gate electrode, so that a portion of the semiconductor layer, the portion being an edge region and facing the gate electrode, has an impurity concentration greater than an impurity concentration of a portion of the semiconductor layer, the portion being a non-edge region and facing the gate electrode. As a result, the above-mentioned problems can be admirably solved, leading to completion of the present invention.

That is, the present invention is a production method of a semiconductor device including a structure in which a semiconductor layer, an insulating film, and a gate electrode are stacked on a main surface of a substrate in this order,

the method comprising an impurity-adding step of:

adding impurities to at least a portion of the semiconductor layer, the portion facing the gate electrode, so that a portion of the semiconductor layer, the portion being an edge region and facing the gate electrode, has an impurity concentration greater than an impurity concentration of a portion of the semiconductor layer, the portion being a non-edge region and facing the gate electrode. This production method permits suppression of generation of the bump in the Vg-Id characteristics curve of the semiconductor device made by the production method of the present invention, which results in suppression of a leakage current.

The production method of the semiconductor device according to the present invention is not particularly limited as long as the above-mentioned steps are included. The production method may include other steps.

Preferred embodiments of the production method of the semiconductor device of the present invention are described in more detail below. The following embodiments may be appropriately employed in combination.

In order to easily obtain the semiconductor layer in which the portion of the semiconductor layer, the portion being an edge region and facing the gate electrode, has an impurity concentration greater than an impurity concentration of the portion of the semiconductor layer, the portion being a non-edge region and facing the gate electrode, it is preferred that the impurity-adding step is performed so that a depth profile of the impurity concentration in the portion of the semiconductor layer, the portion being a non-edge region and facing the gate electrode, has a peak at a position deeper than a position of a peak of a depth profile of the impurity concentration in the portion of the semiconductor layer, the portion being an edge region and facing the gate electrode.

As mentioned above, the impurity-adding step may be performed so that a depth profile of the impurity concentration of a region corresponding to the portion of the semiconductor layer, the portion being a non-edge region and facing the gate electrode, has a peak at a position deeper than a position of a peak of a depth profile of the impurity concentration of a region corresponding to the portion of the semiconductor layer, the portion being an edge region and facing the gate electrode.

In order to easily realize the production method of the semiconductor device of the present invention, the method preferably includes the following embodiments (1) to (3).

(1) in the impurity-adding step, the impurities are added through a covering film covering the portion of the semiconductor layer, the portion facing the gate electrode,

the covering film includes an edge-covering portion and an inside-covering portion,

the edge-covering portion covering the portion of the semiconductor layer, the portion being an edge region and facing the gate electrode,

the inside-covering portion covering the portion of the semiconductor layer, the portion being a non-edge region and facing the gate electrode,

the edge-covering portion having a thickness greater than a thickness of the inside-covering portion;

(2) in the impurity-adding step, the impurities are added to the portion of the semiconductor layer, the portion being an edge region and facing the gate electrode, through a covering film and simultaneously,

the impurities are directly added to the portion of the semiconductor layer, the portion being a non-edge region and facing the gate electrode,

the covering film covering the portion of the semiconductor layer, the portion being an edge region and facing the gate electrode,

the portion of the semiconductor layer, the portion being a non-edge region and facing the gate electrode, being exposed; and

(3) a step of selectively oxidizing a surface of the portion of the semiconductor layer, the portion being an edge region and facing the gate electrode, thereby forming an oxide film thereon,

wherein in the impurity-adding step, the impurities are added to the portion of the semiconductor layer, the portion being an edge region and facing the gate electrode, through the oxide film, and

the impurities are directly added to the portion of the semiconductor layer, the portion being a non-edge region and facing the gate electrode.

In order to easily obtain the semiconductor layer in which the portion of the semiconductor layer, the portion being an edge region and facing the gate electrode, has an impurity concentration greater than an impurity concentration of the portion of the semiconductor layer, the portion being a non-edge region and facing the gate electrode, in the embodiments (1) to (3), it is preferred that the impurity-adding step is performed so that a depth profile of the impurity concentration in the portion of the semiconductor layer, the portion being an edge region and facing the gate electrode, has a peak at a position deeper than the semiconductor layer.

Specifically, in the embodiments (1) to (3), the impurity-adding step may be performed so that a depth profile of the impurity concentration of a region corresponding to the portion of the semiconductor layer, the portion being an edge region and facing the gate electrode, has a peak in the semiconductor layer or the substrate side out of the semiconductor.

In the embodiment (1), configurations of (1-a) and (1-b) are preferred.

(1-a) the covering film is a multi-layer film including an edge-covering film and a channel-covering film,

the edge-covering film covering the portion of the semiconductor layer, the portion being an edge region and facing the gate electrode,

the channel-covering film covering the portion of the semiconductor layer, the portion facing the gate electrode; and (1-b) the covering film is a single layered-film.

A material for the covering film is not particularly limited as long as impurities can pass through the film. More specifically, as the covering film, an insulating film such as an inorganic insulating film and an organic insulating film; a conductive film such as a metal film and a conductive organic film; and the like are preferred.

The above-mentioned impurities are not particularly limited as long as they provide conductivity for an intrinsic semiconductor. More specifically, Group 13 elements such as boron (B) and Group 15 elements such as phosphorus (P) are preferred.

In configuration (1-a), in order to provide a high etch selectivity of the channel-covering film with respect to the edge-covering film and to easily control a difference of thickness of the two covering films, the edge-covering film is preferably made of a material different from a material for the channel-covering film or a sacrificial film removed after the impurity-adding step.

In the configuration (1-a), in order to simplify the production process by using the covering film as an insulating film in the semiconductor device made by the production method of the semiconductor device of the present invention, the edge-covering film and the channel-covering film are inorganic insulating films. According to this, a breakdown withstand voltage of the insulating film can also be improved. A high withstand voltage transistor can also be easily provided in addition to the semiconductor device made by the production method of the semiconductor device of the present invention.

In the above-mentioned configuration (1-b), in order to simplify the production process by using the covering film as the insulating film of the semiconductor device made by the production method of the semiconductor device of the present invention, it is preferred that the edge-covering portion and the inside-covering portion are an inorganic insulating film. According to this, the breakdown withstand voltage of the covering film as the insulating film in the semiconductor device made by the production method of the semiconductor device of a present invention can also be improved. A high withstand voltage transistor can also be easily provided in addition to the semiconductor device made by the production method of the semiconductor device of the present invention.

In the above-mentioned embodiment (2), in order to simplify the production process by using the covering film as the insulating film of the semiconductor device made by the production method of the semiconductor device of the present invention, it is preferred that the covering film is an inorganic insulating film. According to this, the breakdown withstand voltage of the covering film as the insulating film can also be improved. A high withstand voltage transistor can also be easily provided in addition to the semiconductor device made by the production method of the semiconductor device of the present invention.

In the embodiment (2), it is preferred that the covering film is a sacrificial film removed after the impurity-adding step. In such an embodiment, the material for the covering film can be more freely selected.

In order to suppress the generation of the bump in the Vg-Id characteristics of the semiconductor device made by the production method of the semiconductor device of the present invention, the production method of the semiconductor device of the present invention preferably has the following embodiments or configurations (4) to (7).

(4) the semiconductor layer has an edge having a forward tapered cross section, and

the portion of the semiconductor layer, the portion being an edge region and facing the gate electrode, is a tapered portion with a thickness smaller than a thickness of a non-edge inside portion of the semiconductor layer;

(5) the semiconductor layer is formed by etching in a patterning step, and

the portion of the semiconductor layer, the portion being an edge region and facing the gate electrode, is a portion having a structural defect due to the etching in the patterning step;

(6) the portion of the semiconductor layer, the portion being an edge region and facing the gate electrode, is a portion overlapping with a portion of the insulating film on the semiconductor layer, the portion of the insulating film having a thickness smaller than a thickness of the insulating film positioned on an non-edge inside portion of the semiconductor layer; and
(7) the portion of the semiconductor layer, the portion being an edge region and facing the gate electrode, is a portion overlapping with a portion of the insulating film on the semiconductor layer, the portion of the insulating film having a structural defect much more than a portion of the insulating film positioned on an non-edge inside portion of the semiconductor layer has.

In order to easily perform the production method of the semiconductor device of the present invention using a common production apparatus, in the above-mentioned impurity-adding step, impurities are added to at least the portion of the semiconductor layer, the portion facing the gate electrode, so that a region facing the gate electrode and bounded by an outline of the semiconductor layer and a line 0.1 μm or more inward away therefrom has an impurity concentration greater than that of the rest region.

If heavily doped region is a region bounded by an outline of the semiconductor layer and a line 0.1 μm or less inward away therefrom and facing the gate electrode, it may be difficult to realize the production method of the semiconductor device of the present invention using a common production apparatus.

The present invention is also a semiconductor device comprising a structure in which a semiconductor layer, an insulating film, and a gate electrode are stacked on a main surface of a substrate in this order,

wherein the semiconductor device has a portion of the semiconductor layer, the portion being an edge region and facing the gate electrode, having an impurity concentration greater than an impurity concentration of a portion of the semiconductor layer, the portion being a non-edge region and facing the gate electrode. (hereinafter, also referred to as “a first semiconductor device of the present invention”) According to the first semiconductor device, the generation of the bump in the Vg-Id characteristics curve can be suppressed, which permits suppression of a leakage current.

The configuration of the first semiconductor device of the present invention is not particularly limited as long as it essentially includes the above-mentioned components. The semiconductor device may or may not include other components.

Preferable embodiments of the first semiconductor device of the present invention are described in more detail below. The following embodiments may be appropriately employed in combination.

In order to easily obtain the semiconductor layer in which the portion of the semiconductor layer, the portion being an edge region and facing the gate electrode, has an impurity concentration greater than an impurity concentration of the portion of the semiconductor layer, the portion being a non-edge region and facing the gate electrode, it is preferred that in the semiconductor layer, a peak of a depth profile of the impurity concentration in the portion of the semiconductor layer, the portion being a non-edge region and facing the gate electrode, is at a position deeper than a position of a peak of a depth profile of the impurity concentration in the portion of the semiconductor layer, the portion being an edge region and facing the gate electrode.

As mentioned above, in the semiconductor layer, a peak of a depth profile of the impurity concentration of a region corresponding to the portion of the semiconductor layer, the portion being a non-edge region and facing the gate electrode, may be at a position deeper than a position of a peak of a depth profile of the impurity concentration of a region corresponding to the portion of the semiconductor layer, the portion being an edge region and facing the gate electrode.

In order to more easily provide the first semiconductor device of the present invention, it preferably includes the following configurations (8) to (10).

(8) the insulating film is a multi-layer film including an edge insulating film and a channel insulating film, the edge insulating film covering the portion of the semiconductor layer, the portion being an edge region and facing the gate electrode, the channel insulating film covering the portion of the semiconductor layer, the portion facing the gate electrode;
(9) the insulating film includes an edge-covering portion and an inside-covering portion, the edge-covering portion covering the portion of the semiconductor layer, the portion being an edge region and facing the gate electrode, the inside-covering portion covering the portion of the semiconductor layer, the portion being a non-edge region and facing the gate electrode, the edge-covering portion and the inside-covering portion being different in thickness; and
(10) the semiconductor comprises an oxide film on a gate electrode side-surface of the portion of the semiconductor layer, the portion being an edge region and facing the gate electrode.

In the above-mentioned configuration (8), in order to even more easily provide the first semiconductor device of the present invention, it is preferred that the edge insulating film is made of a material different from a material for the channel insulating film.

In the above-mentioned configuration (8), in order to even more easily provide the first semiconductor device of the present invention, it is preferred that the edge insulating film and the channel insulating film are inorganic insulating films. According to this, a breakdown withstand voltage of the insulating film in the first semiconductor device of the present invention can also be improved. A high withstand voltage transistor can also be easily provided in addition to the first semiconductor device of the present invention.

In the above-mentioned configuration (9), in order to even more easily provide the first semiconductor device of the present invention, it is preferred that the edge-covering portion and the inside-covering portion are an inorganic insulating film. According to this, a breakdown withstand voltage of the insulating film in the first semiconductor device of the present invention can also be improved. A high withstand voltage transistor can also be provided easily in addition to the first semiconductor device of the present invention.

In order to suppress the generation of the bump in the Vg-Id characteristics of the first semiconductor device of the present invention, the first semiconductor device of the present invention preferably includes the following configurations (11) to (14).

(11) the semiconductor layer has an edge having a forward tapered cross section,

the portion of the semiconductor layer, the portion being an edge region and facing the gate electrode, is a tapered portion with a thickness smaller than a thickness of a non-edge inside portion of the semiconductor layer;

(12) the semiconductor layer is formed by etching in a patterning step, and

the portion of the semiconductor layer, the portion being an edge region and facing the gate electrode, is a portion having a structural defect due to the etching in the patterning step.

(13) the portion of the semiconductor layer, the portion being an edge region and facing the gate electrode, is a portion overlapping with a portion of the insulating film on the semiconductor layer, the portion of the insulating film having a thickness smaller than a thickness of the insulating film positioned on a non-edge inside portion of the semiconductor layer; and
(14) the portion of the semiconductor layer, the portion being an edge region and facing the gate electrode, is a portion overlapping with a portion of the insulating film on the semiconductor layer, the portion of the insulating film having a structural defect much more than a portion of the insulating film positioned on a non-edge inside portion of the semiconductor layer has.

In order to easily provide the first semiconductor device of the present invention using a common production apparatus, the portion of the semiconductor layer, the portion being an edge region and facing the gate electrode, is a region bounded by an outline of the semiconductor layer and a line 0.1 μm or more inward away therefrom and facing the gate electrode.

If the line is positioned 0.1 μm or less inward away from the outline, it may be difficult to provide the semiconductor device of the present invention using a common production apparatus.

The present invention is also a semiconductor device comprising a structure in which a semiconductor layer, an insulating film, and a gate electrode are stacked on a main surface of a substrate in this order,

wherein the semiconductor layer has a portion of the semiconductor layer, the portion being an edge region and facing the gate electrode, having a sheet resistance lower than a sheet resistance of a portion of the semiconductor layer, the portion being a non-edge region and facing the gate electrode. (hereinafter, also referred to as “a second semiconductor device of the present invention”) Also according to the second semiconductor device, the generation of the bump in the Vg-Id characteristics curve can be suppressed, which permits suppression of a leakage current.

The configuration of the second semiconductor device of the present invention is not particularly limited as long as it essentially includes the above-mentioned components. The semiconductor device may or may not include other components.

The second semiconductor device of the present invention preferably includes the following configurations from the same viewpoint as in the first semiconductor device of the present invention. The following embodiments may be appropriately employed in combination.

The following configurations are preferred.

(15) the insulating film is a multi-layer film including an edge insulating film and a channel insulating film, the edge insulating film covering the portion of the semiconductor layer, the portion being an edge region and facing the gate electrode, the channel insulating film covering the portion of the semiconductor layer, the portion facing the gate electrode;
(16) the insulating film includes an edge-covering portion and an inside-covering portion, the edge-covering portion covering the portion of the semiconductor layer, the portion being an edge region and facing the gate electrode, the inside-covering portion covering the portion of the semiconductor layer, the portion being a non-edge region and facing the gate electrode, the edge-covering portion and the inside-covering portion being different in thickness; and
(17) the semiconductor device comprises an oxide film on a gate electrode side-surface of the portion of the semiconductor layer, the portion being an edge region and facing the gate electrode.

In the configuration (15), it is preferred that the edge insulating film is made of a material different from a material for the channel insulating film.

In the configuration (15), it is preferred that the edge insulating film and the channel insulating film are inorganic insulating films.

In the configuration (16), it is preferred that the edge-covering portion and the inside-covering portion are an inorganic insulating film.

The second semiconductor device of the present invention preferably includes the following configurations (18) to (21).

(18) the semiconductor layer has an edge having a forward tapered cross section,

the portion of the semiconductor layer, the portion being an edge region and facing the gate electrode, is a tapered portion with a thickness smaller than a thickness of a non-edge inside portion of the semiconductor layer;

(19) the semiconductor layer is formed by etching in a patterning step, and

the portion of the semiconductor layer, the portion being an edge region and facing the gate electrode, is a portion having a structural defect due to the etching in the patterning step;

(20) the portion of the semiconductor layer, the portion being an edge region and facing the gate electrode, is a portion overlapping with a portion of the insulating film on the semiconductor layer, the portion of the insulating film having a thickness smaller than a thickness of the insulating film positioned on a non-edge inside portion of the semiconductor layer; and
(21) the portion of the semiconductor layer, the portion being an edge region and facing the gate electrode, is a portion overlapping with a portion of the insulating film on the semiconductor layer, the portion of the insulating film having a structural defect much more than a portion of the insulating film positioned on a non-edge inside portion of the semiconductor layer has.

It is preferable that the portion of the semiconductor layer, the portion being an edge region and facing the gate electrode, is a region bounded by an outline of the semiconductor layer and a line 0.1 μm or more inward away therefrom and facing the gate electrode.

The present invention is also a semiconductor device comprising:

a structure in which a semiconductor layer, an insulating film, and a gate electrode are stacked on a main surface of a substrate in this order,

wherein the semiconductor device includes an N-channel transistor and/or a P-channel transistor, the N-channel transistor satisfying the following formula (X), the P-channel transistor satisfying the following formula (Y):

Vth,e>Vth,m (X)

Vth,e<Vth,m (Y)

wherein in the formulae (X) and (Y), Vth,e represents a threshold voltage of transistor characteristics of a portion of the semiconductor layer, the portion being an edge region and facing the gate electrode, and Vth,m represents a threshold voltage of transistor characteristics of a portion of the semiconductor layer, the portion being a non-edge region and facing the gate electrode. (hereinafter, also referred to as “a third semiconductor device of the present invention”). Also according to the third semiconductor device, the generation of the bump in the Vg-Id characteristics curve can be suppressed, which permits suppression of a leakage current.

The configuration of the third semiconductor device of the present invention is not particularly limited as long as it essentially includes the above-mentioned components. The semiconductor device may or may not include other components.

The third semiconductor device of the present invention preferably has the following embodiments from the same viewpoint as in the first semiconductor device of the present invention. The following embodiments may be appropriately employed in combination.

The following configurations are preferred.

(22) the insulating film is a multi-layer film including an edge insulating film and a channel insulating film, the edge insulating film covering the portion of the semiconductor layer, the portion being an edge region and facing the gate electrode, the channel insulating film covering the portion of the semiconductor layer, the portion facing the gate electrode;
(23) the insulating film includes an edge-covering portion and an inside-covering portion, the edge-covering portion covering the portion of the semiconductor layer, the portion being an edge region and facing the gate electrode, the inside-covering portion covering the portion of the semiconductor layer, the portion being a non-edge region and facing the gate electrode, the edge-covering portion and the inside-covering portion being different in thickness; and
(24) the semiconductor comprises an oxide film on a gate electrode side-surface of the portion of the semiconductor layer, the portion being an edge region and facing the gate electrode.

In the configuration (22), the edge insulating film is made of a material different from a material for the channel insulating film.

In the configuration (22), the edge insulating film and the channel insulating film are inorganic insulating films.

In the configuration (23), the edge-covering portion and the inside-covering portion are an inorganic insulating film.

The third semiconductor device of the present invention preferably includes the following configurations (25) to (28).

(25) the semiconductor layer has an edge having a forward tapered cross section,

the portion of the semiconductor layer, the portion being an edge region and facing the gate electrode, is a tapered portion with a thickness smaller than a thickness of a non-edge inside portion of the semiconductor layer;

(26) the semiconductor layer is formed by etching in a patterning step, and

the portion of the semiconductor layer, the portion being an edge region and facing the gate electrode, is a portion having a structural defect due to the etching in the patterning step.

(27) the portion of the semiconductor layer, the portion being an edge region and facing the gate electrode, is a portion overlapping with a portion of the insulating film on the semiconductor layer, the portion of the insulating film having a thickness smaller than a thickness of the insulating film positioned on a non-edge inside portion of the semiconductor layer; and
(28) the portion of the semiconductor layer, the portion being an edge region and facing the gate electrode, is a portion overlapping with a portion of the insulating film on the semiconductor layer, the portion of the insulating film having a structural defect much more than a portion of the insulating film positioned on a non-edge inside portion of the semiconductor layer has.

The portion of the semiconductor layer, the portion being an edge region and facing the gate electrode, is a region bounded by an outline of the semiconductor layer and a line 0.1 μm or more inward away therefrom and facing the gate electrode.

### EFFECT OF THE INVENTION

According to the production method of the semiconductor device of the present invention, the semiconductor device where a leakage current is suppressed can be produced.

### BEST MODES FOR CARRYING OUT THE INVENTION

The present invention is described in more detail below with reference to Embodiments using drawings, but not limited thereto.

FIG. 1 is a schematic view showing a configuration of the semiconductor device in accordance with Embodiment 1. FIG. 1(a) is a plan view thereof. FIG. 1(b) is a sectional view taken along line Y1-Y2 in FIG. 1(a). FIG. 1(c) is a sectional view taken along line X1-X2 in FIG. 1(a). In FIG. 1(a), the thick line is an outline of a first insulating film. FIG. 2 is a conceptual view showing gate voltage-drain current characteristics of the TFT in accordance with Embodiment 1. In FIG. 2, the lower arrow shows a shift amount of transistor characteristics of a channel edge region and a shift direction thereof and; the upper arrow shows a shift amount of transistor characteristics of a channel body region and a shift direction thereof.

A TFT 10 of the present Embodiment includes, as shown in FIG. 1, a structure in which a base layer (a base coat layer) 17, an island-shaped semiconductor layer 20, a first insulating film 12, a second insulating film 13, and a gate electrode 14 are stacked on a substrate 11 in this order. The TFT 10 further includes an interlayer insulating film 15 covering the above-mentioned components and wirings 16a and 16b formed on the interlayer insulating film 15. The gate electrode 14 is arranged to cross the central part of the semiconductor layer 20. The semiconductor layer 20 has a channel region 21 and source-drain regions 22, the channel region 21 being provided in a region facing the gate electrode 14, the source-drain regions 22 being provided in a region other than the channel region 21. The wirings 16a and 16b are connected to the source-drain regions 22 through contact holes 18a and 18b, respectively, the contact holes being formed in the interlayer insulating film 15 in a portion facing the source-drain regions 22. As just described, the TFT 10 is a planar TFT including a single drain structure. Furthermore, the TFT 10 of the present Embodiment preferably includes a structure where a semiconductor layer, an insulating film, and a gate electrode are stacked in this order from a substrate side. The first insulating film 12 overlaps with edge portions of the semiconductor layer 20 without overlapping with an inside portion of the semiconductor layer containing parts where the wirings 16a and 16b are contact with the source-drain regions 22. The second insulating film 13 is formed to cover the entire region of the semiconductor layer 20. Therefore, the insulating film having a large thickness is formed in a region corresponding to the edge portions of the semiconductor layer 20, while the insulating film having a small thickness is formed in a region corresponding to the non-edge portion of the semiconductor layer 20.

In addition to the single drain structure, the TFT 10 may have another structure, such as an LDD structure, a GOLD structure, and the like.

In the present description, the source-drain regions 22 are regions that function as source and/or drain of a TFT. That is, if one of the source-drain regions 22 functions as source, the other functions as drain. The source-drain regions 22 of the semiconductor layer 20 are a region with conductivity obtained by heavily doping an intrinsic semiconductor with impurities (donors or acceptors). The channel region 21 is obtained also by lightly doping the semiconductor layer 20 with impurities in order to adjust a threshold voltage (Vth) of the TFT 10 to a desired level, that is, by channel doping.

The edge portions of the channel region 21 have an impurity concentration greater than that of the non-edge inside portion, which is other than the edge portions, of the channel region 21. That is, a portion of the semiconductor layer 20, the portion being an edge region and facing the gate electrode 14, (hereinafter, also referred to as “channel edge region”. The channel edge region, which are the shaded region in FIGS. 1(a) and 1(b)), is more heavily doped with impurities than a region of a non-edge portions, i.e, a portion of the semiconductor layer 20, the portion being an inside region and facing the gate electrode 14 (hereinafter, also referred to as “channel body region”) is done. In addition, a sheet resistance value in the channel edge region is smaller than that in the channel body region. Therefore, a leakage current generated in the TFT 10 can be suppressed.

A mechanism of suppression of a leakage current in the TFT 110 is described in more detail below.

The reason why a curve of gate voltage (Vg)-drain current (Id) characteristics of the conventional TFT 110 has a bump is described. In the conventional TFT 110, the channel body region and the channel edge region are different in transistor characteristics. This is interpreted to be due to the fact that the insulating film in the channel edge region has a thin thickness. In addition, a structural defect of the edge portion of the semiconductor layer due to etching or the like in a patterning process of the semiconductor layer or a structural defect of the insulating film on the edge portion of the semiconductor layer may cause deterioration of the transistor characteristics of the channel edge region. As a result, the channel body region and the channel edge region are different in transistor characteristics, specifically, in Vth. Thus, a parasitic transistor having characteristics different from that of the channel body region is formed in the channel edge region. As a result, the Vg-Id characteristics curve might have a bump particularly at about Vth. Furthermore, in an N-channel transistor, a bump tends to be easily generated because Vth of the parasitic transistor formed in the channel edge region is particularly small and a current amount is also small. In the N-channel transistor, Vth shifts towards a positive direction by doping the channel with, for example, boron (B) as an impurity. That is, the channel doping allows the transistor characteristics to shift toward a positive direction or a negative direction, on an impurity concentration, that is, depending on a resistance. However, in the conventional TFT 110, both the channel body region and the channel edge region are doped with impurities to have the same impurity concentration. As a result, as shown in FIG. 13, the transistor characteristics of the channel body region also shift similar to that of the channel edge region (see the arrow in FIG. 13), and the bump still remains to be observed.

In contrast, in the TFT 10 of the present Embodiment, an impurity concentration (a sheet resistance) of the channel edge region is greater than that of the channel body region. So, transistor characteristics of the channel edge region, specifically, Vth,e can be significantly shifted compared with transistor characteristics of the channel body region, specifically, Vth,m, as shown in FIG. 2. (See the arrows in FIG. 2). The lower arrow shows a shift amount and a shift direction of transistor characteristics of the channel edge region, and the upper arrow shows a shift amount and a shift direction of transistor characteristics of the channel body region) As a result, generation of the bump can be suppressed.

As mentioned above, when the TFT 10 of the present Embodiment is an N-channel transistor, a threshold voltage of the transistor characteristics of the channel edge region Vth,e shifts more toward a positive direction than a threshold voltage of the transistor characteristics of the channel body region Vth,m does. In contrast, when the TFT 10 of the present Embodiment is a P-channel transistor, a threshold voltage Vth,m of the transistor characteristics due to the channel edge region shifts more toward a negative direction than a threshold voltage Vth,m of the transistor characteristics due to the channel body region does. That is, the threshold voltage Vth,e of the transistor characteristics due to the channel edge region and the threshold voltage Vth,m of the transistor characteristics due to the channel body region satisfy the following formula (X) when the TFT 10 of the present Embodiment is an N-channel transistor and satisfy the following formula (Y) when the TFT of the present Embodiment is a P-channel transistor.

Vth,e>Vth,m (X)

Vth,e<Vth,m (Y)

Vth,e of the channel edge region and Vth,m of the channel body region can be determined by the following methods (1) to (3):

(1) a transistor composed of only the channel edge region and a transistor composed of only the channel body region are measured for TFT characteristics, thereby determining the Vth,e and the Vth,m, independently.
(2) transistors different in channel width, i.e., in proportion between the channel edge region and the channel body region are measured for TFT characteristics, thereby simply estimating the Vth,e and the Vth,m from the resulting TFT characteristics and a shape of a bump due to the characteristics.
(3) The channel region is determined for impurity concentration by secondary ion mass spectrometry (SIMS) and the like, thereby estimating the Vth,e and the Vth,m.

In the conventional TFT 110, a dielectric breakdown between the gate electrode 114 and the semiconductor layer 120 tends to be generated in the vicinity of the edges of the semiconductor layer 120. This is because, at the edge portions of the semiconductor layer 120, a coating property of the insulating film 112 is deteriorated, and a thickness of the insulating film is decreased. However, in the TFT 10 of the present Embodiment, the first insulating film 12 is formed to cover at least the channel edge region. So the channel edge region is covered with two insulating layers, the first and second insulating films 12 and 13. Accordingly, according to the TFT 110 of the present Embodiment, a breakdown withstand voltage of the insulating film can be improved.

The production method of the semiconductor device of the present Embodiment is described below. FIGS. 3(a) and 3(b) are plan views schematically showing the semiconductor device in accordance with a modified example of Embodiment 1. The thick lines in FIGS. 3(a) and 3(b) are outlines of the first insulating film. FIG. 4 is a cross-sectional view schematically showing a configuration of the semiconductor device in accordance with Embodiment 1 in the respective production steps.

First, on the main surface of a substrate 11, a base layer 17 made of a silicon-containing inorganic insulating film (for example, a film made of SiO₂, SiN, or SiNO) with a thickness of 30 to 700 nm (preferably 50 to 400 nm) is formed by plasma CVD (Chemical Vapor Deposition) or sputtering. Thereby, even when a glass substrate is used as the substrate 11, diffusion of impurities, including alkali metals and the like, from the substrate 11 can be prevented.

The base layer 17 may have a single insulating film structure or a multi-layer structure of two or more insulating films. A material for the substrate 11 is not particularly limited. A glass, quartz, or silicon substrate, a substrate having a metal or stainless surface on which an insulating film has been formed, a heat-resistant plastic substrate that can withstand treatment temperatures, and the like, may be used as the substrate 11. Among them, the glass substrate is preferred. A substrate that is used in a display device such as a liquid crystal display device is preferred as the substrate 11. As mentioned above, the semiconductor device of the present Embodiment is preferred as a semiconductor device a display device includes, and particularly preferred as a semiconductor device that is arranged in a display device substrate.

Then, on the base layer 17, an island-shaped semiconductor layer (active layer) 20 with a thickness of 20 to 100 nm (preferably 30 to 70 nm) is formed by patterning. More specifically, the semiconductor layer 20 is formed as follows: an amorphous semiconductor film having an amorphous structure is formed by sputtering, LPCVD (low-pressure CVD), or plasma CVD; the film is crystallized by laser; and the resulting crystalline semiconductor film is patterned into a desired shape by photolithography. Thus, the semiconductor layer 20 having a forward tapered cross section (such a shape that a side on the upper layer side is shorter than a side on the substrate side) in which a taper angle (an angle made by a slope edge of the semiconductor layer 20 and a surface of the base layer 17) is 10° to 89° (preferably 20° to 80°) is formed. A material for the semiconductor layer 20 is not particularly limited, and silicon, a silicon germanium (SiGe) alloy, and the like are preferably used. Silicon is more preferably used.

The crystallization of the semiconductor layer 20 may include solid-phase growth in which a catalyst metal such as nickel (Ni) is applied on the amorphous semiconductor film, and heat treatment of the film by laser and the like is performed. As a result, a CG (continuous grain) silicon film can be formed.

The crystallization by laser may be performed as follows: the film is irradiated with laser only once in atmospheric air containing approximately 20% of oxygen; or the film is irradiated with laser in atmospheric air and irradiated again in nitrogen atmosphere. According to the latter method, the semiconductor layer 20 can be formed to have a more flat surface, thereby improving the film forming ability of the first insulating film 12 that is to be formed on the semiconductor layer 20.

The first insulating film 12 is formed to have a thickness of 10 to 100 nm (preferably 30 to 70 nm). A silicon-containing inorganic insulating film (for example, a SiO₂ film, a SiN film, or a SiNO film) formed by plasma CVD or sputtering may be preferably used as the first insulating film 12. The SiO₂ film is particularly preferred as the first insulating film 12. The first insulating film 12 may have a single insulating film structure or a multi-layer structure of two or more insulating films that are made of different insulating materials. Such a film 12 with the multi-layer structure is preferably arranged on the semiconductor layer 20 so that the SiO₂ film is in contact with the layer 20. In such a multi-layer structure in which the semiconductor layer 20 and the SiO₂ film are alternately stacked, when the semiconductor layer 20 is a silicon layer, an interface state between the first insulating film 12 and the semiconductor layer 20 can be reduced, which leads to an improvement in electrical characteristics of the TFT 10.

Then, a resist is patterned on the first insulating layer 12 by photolithography, and the first insulating layer 12 in at least the channel body region is removed by etching using etchants such as hydrogen fluoride (HF). More specifically, the first insulating film 12 in a region overlapping with the inside portion of the semiconductor layer 20, except for the edge portion of the semiconductor layer 20, is removed. Then, the resist formed on the first insulating film 20 is removed.

The first insulating film 12 may be patterned to selectively overlap with the channel edge region as shown in FIG. 3(a), and may be patterned to overlap with the edge portion of the semiconductor layer 20 in a channel width direction as shown in FIG. 3(b).

The second insulating film 13 is then formed to have a thickness of 10 to 100 nm (preferably 30 to 70 nm). Thereby, the thickness of the insulating film (the first insulating film 12 and the second insulating film 13) on the edge portion of the semiconductor layer 20 is greater than that of the insulating film (the second insulating film 13) on the inside portion of the semiconductor layer 20. In this case, the insulating film (the first insulating film 12 and the second insulating film 13) in the channel edge region may have a thickness slightly greater than that of the insulating film (the second insulating film 13) in the channel body region, and preferably has a thickness 1.2 times or more, and more preferably 1.5 times or more as great as that of the insulating film in the channel body region. A silicon-containing inorganic insulating film (for example, a SiO₂ film, a SiN film, a SiNO film) formed by plasma CVD or sputtering may be preferably used as the second insulating film 13. The SiO₂ film is particularly preferably used as the second insulating film 13. The second insulating film 13 may have a single insulating film structure or a multi-layer structure of two or more insulating films that are made of different insulating materials. Such a film 13 with the multi-layer structure is preferably arranged on the semiconductor layer 20 so that the SiO₂ film is in contact with the layer 20. In such a multi-layer structure in which the semiconductor layer 20 and the SiO2 film are alternately stacked, electrical characteristics of the TFT 10 can be improved similarly to the case of the first insulating film 12.

Then, in order to control a threshold voltage of the TFT 10, impurities are added by ion implantation or ion doping (channel doping) into the entire semiconductor layer 20 through the first and second insulating films 12 and 13. Thus, the first and second insulating films 12 and 13 preferably function as a covering film that allows impurities to permeate it. The first insulating film 12 also functions as an edge-covering film. The second insulating film 13 also functions as a channel-covering film. More specifically, as shown in FIG. 4, an impurity implantation energy is adjusted so that a depth profile of the impurity concentration in the channel edge region has a peak Rp,e in the semiconductor layer 20 or in a layer that is positioned lower than the semiconductor layer 20 (on the substrate 11 side) (in the present Embodiment, the semiconductor layer 20). In this case, the impurity concentration is monotonically increased with increasing the depth and after reaching the peak, the impurity concentration is monotonically decreased. That is, the impurity concentration varies along a parabolic curve in the depth direction. Therefore, the position of the peak Rp,m of the impurity concentration in the channel body region is positioned deeper than that of the peak Rp,e. As a result, the impurity concentration of the channel edge region where the insulating film is thick (the white arrow in FIG. 4) can be increased, while the impurity concentration of the channel body region where the insulating film is thin (the solid line arrow in FIG. 4) can be decreased. In order to make the TFT 10 as an N-channel TFT, Group 13 elements such as boron (B) are preferably used as the doped impurity. In order to make the TFT 10 as a P-channel TFT, Group 15 elements such as Phosphorus (P) are preferably used as the doped impurity. As a method for adding impurities in the present Embodiment, ion doping is preferred when the impurity addition is provided for a large-sized substrate.

The implantation energy can be adjusted by varying an acceleration voltage of an ion implanter or an ion doping system. Specifically, the acceleration voltage may be set in the range of about 5 to about 80 keV.

A dose amount of the impurity may be appropriately adjusted in order to obtain a desired Vth.

In order to make the TFT 10 as an N-channel TFT, the dose amount may be from about 1×10¹² to about 1×10¹⁴ cm⁻². In order to make the TFT 10 as a P-channel TFT, the dose amount may be from about 1×10¹¹ to about 5×10¹³ cm⁻².

The difference of the impurity concentrations between the channel edge region and the channel body region can be appropriately set. When the impurity concentration of the channel edge region is even a little greater than that of the channel body region, the size of the bump can be reduced. The impurity concentration of the channel edge region is preferably 1.2 times or more, and more preferably 1.5 times or more as great as that of the channel body region. More specifically, in order to make the TFT 10 as an N-channel TFT, the impurity concentration of the channel edge region may be from about 1×10¹⁶ to about 1×10²⁰ cm⁻³ and the impurity concentration of the channel body region may be from about 1×10¹⁶ to about 1×10¹⁸ cm⁻³. In order to make the TFT 10 as a P-channel TFT, the impurity concentration of the channel edge region may be from about 1×10¹⁵ to about 5×10¹⁹ cm⁻³ and the impurity concentration of the channel body region may be from about 1×10¹⁵ to about 1×10¹⁸ cm⁻³.

The impurity concentration of each of the channel edge region and the channel body region can be measured by SIMS and the like and can be also estimated by sheet resistance measurement.

The channel doping may be performed after patterning the first insulating film 12 and before formation of the second insulating film 13. Thus, the channel edge region can be doped with impurities through the first insulating film 12, and the channel body region can be directly doped with impurities. That is, also according to this embodiment, the channel edge region having an impurity concentration greater than the channel body region can be provided.

Then, a conductive film is formed by sputtering to have a thickness of 200 to 600 nm (preferably 300 to 400 nm) and the film is then patterned into a desired shape by photolithography to form a gate electrode 14. The gate electrode 14 is formed across the center of the semiconductor layer 20. Preferred examples of a material for the gate electrode 14 include high melting point metals such as tantalum (Ta), tungsten (W), titanium (Ti), and molybdenum (Mo), and alloys or compounds, containing these high melting point metals as a main component. Nitrides are preferred as the compound containing the high melting point metals as a main component. The gate electrode 14 may have a structure in which conductive films made of these materials are stacked.

Then using the gate electrode 14 as a mask, impurities, such as boron (B) ions and phosphorus (P) ions, are doped into the semiconductor layer 20 in a self-alignment manner at 40 kV and at 5×10¹⁵ to 1×10¹⁶ cm⁻² (heavy doping for source-drain) by ion implantation or the ion doping. The impurity concentration of a region corresponding to the source-drain region 22 of the semiconductor layer 20 is about 1×10¹⁹ to about 1×10²⁰ cm⁻³. Thereby, the region that faces (overlaps with) the gate electrode 14 of the semiconductor layer 20 can be defined as the channel region 21 in a self-alignment manner. A heavily doped region is formed in a region other than the channel region 21 of the semiconductor layer 20. The heavily doped region functions as the source-drain region 22. As impurities used for the heavy doping for source-drain, Group 15 elements, such as phosphorus (P), are preferred in order to make the TFT 10 as an N-channel TFT, Group 13 elements such as boron (B) are preferred in order to make the TFT 10 as a P-channel TFT.

In this case, the source-drain regions 22 are doped with unipolar impurities. When a CG silicon film is used as the semiconductor layer 20, for gettering of the catalyst metal such as Ni, an edge region of the semiconductor layer 20 except for a region facing the gate electrode 14, and/or a region that has no influences on transistor characteristics except for the contact parts of the source-drain regions 22, may be doped with impurities with reverse polarity.

Then the interlayer insulating film 15 is formed to have a thickness of 0.3 to 1.5 μm (preferably 0.5 to 1.0 μm). A silicon-containing insulating film (for example, a SiO₂ film, a SiN film, a SiNO film) formed by plasma CVD or sputtering can be used as the interlayer insulating film 15. The interlayer insulating film 15 may have a single insulating film structure or a multi-layer structure of two or more insulating layers. The interlayer insulating film 15 is particularly preferably a multi-layer film where a hydrogen-containing silicon nitride (SiN: H) film with a thickness of 0.1 to 0.4 μm and a SiO₂ film with a thickness of 0.3 to 0.6 μm are stacked from the substrate 11 side. Then the whole substrate 11 is heated at 400° C. to 450° C. for about 0.5 to 1 hour, thereby hydrogenating and activating the semiconductor layer 20. At this time, hydrogen contained in the silicon nitride film is diffused into the semiconductor layer 20, and a dangling bond is terminated. Therefore, the use of the hydrogen-containing silicon nitride film as a underlying layer of the interlayer insulating film 15 permits effective hydrogenation of the semiconductor layer 20.

Then, contact holes 18a and 18b are formed in the interlayer insulating film 15 and the second insulating film 13 in the source-drain regions 22 by photolithography. The step of hydrogenating and activating the semiconductor layer 20 may be performed after formation of the contact holes 18a and 18b.

Finally, a conductive film is formed by sputtering to have a thickness of 300 to 1000 nm (preferably 400 to 800 nm) and the conductive film is then patterned into a desired shape by photolithography to form wirings 16a and 16b. As a result, the TFT 10 of the present Embodiment can be completed. Preferred examples of a material for the wirings 16a and 16b include low resistance metals such as aluminum (Al), copper (Cu), and silver (Ag), and alloys or compounds, containing these low resistance metals as a main component. The wirings 16a and 16b may have a structure in which conductive films made of these materials are stacked.

If necessary, a multi-layer wiring structure may be formed, or a protective film may be formed using a resin film and/or a silicon nitride film after formation of the wirings 16a and 16b.

As described above, according to the production method of the semiconductor device of the present Embodiment, the semiconductor device including, on the substrate 11, the TFT 10 showing the Vg-Id characteristics curve having the suppressed bump, that is, the TFT 10 having suppressed leakage current, can be easily provided.

Other preferable embodiments and modified embodiments of the present Embodiment are described below.

As mentioned above, the generation of the bump in the curve showing Vg-Id characteristics is caused by: (a) a small thickness of the insulating film on the channel edge region, (b) a structural defect of the channel edge region, (c) a structural defect of the insulating film on the channel edge region, and the like. The structural defect (b) may be caused by etching damage in patterning of the semiconductor layer, and a tapered portion of the semiconductor layer may be suffered from this damage. The structural defect (c) may be caused by a decrease in quality of the insulating film on the channel edge region, that is, on a shoulder portion of the semiconductor layer. So, the impurity concentration of the regions described in (a) to (c) is increased compared with that of the channel body region, which effectively suppresses the generation of the bump. That is, the first insulating film 12 is preferably patterned to satisfy at least one of, more preferably all of the following embodiments: the first insulating film 12 in at least a portion with a small thickness on the channel edge region is left; at least the channel edge region that has a structural defect caused by etching in patterning the semiconductor layer 20 is covered with the first insulating film 12; the first insulating film 12 in at least a portion having a structural defect on the channel edge region is left; and at least a tapered portion of the semiconductor layer 20 is covered with the first insulating film 12. Further, the thus-obtained channel edge region where impurities are heavily doped with impurities compared with the channel body region, preferably satisfies at least one of, more preferably all of the following embodiments: the channel edge region is a portion overlapping with the first insulating film 12 having a thickness thinner than that of the film 12 on the channel body region; the channel edge region is a portion having a structural defect due to etching in the patterning process of the semiconductor layer 20; the channel edge region is a portion positioned on the channel edge region overlapping with the first insulating film 12 having much more structural defects than the first insulating film 12 on the channel body region; and the channel edge region is a tapered portion of the semiconductor layer, having a thickness thinner than that in the channel body region.

In order to ensure that the first insulating film 12 on the channel edge region is left even if misalignment of a photomask and/or a variation in pattern size occur (s) when patterning a resist formed on the first insulating film 12, the first insulating film 12 is preferably patterned so that an edge of the first insulating film 12 (outline of the first insulating film 12) is positioned 0.1 μm or more (preferably 0.2 μm) inward away from a line segment of an outline of the semiconductor layer 20, the line segment and the gate electrode 14 overlapping with each other. Thereby, the first insulating film 12 on the channel edge region can be surely left by using a common production apparatus. In this respect, the channel of the semiconductor layer 20 is preferably doped with impurities so that a region facing the gate electrode 14 and bounded by an outline of the semiconductor layer 20 and a line 0.1 μm or more (more preferably 0.2 μm or more) inward away therefrom has an impurity concentration greater than that of the rest region. In addition, in the TFT 10, it is preferred that the region facing the gate electrode 14 and bounded by an outline of the semiconductor layer 20 and a line 0.1 μm or more (more preferably 0.2 μm or more) inward away therefrom has an impurity concentration greater than that of the rest region. A width W1 (a length in a channel width direction) of the region that overlaps with the channel edge region of the first insulating film 12 is not greater than a channel width W of the channel body region (an opening width of the first insulating film 12). When the width W1 of the region that overlaps with the channel edge region of the first insulating film 12 is greater than the channel width W, the increased effect of the transistor characteristics of the channel edge region may cause variation in transistor characteristics of the channel body region. In this respect, the channel of the semiconductor layer 20 is preferably doped with impurities so that a region facing the gate electrode 14 and bounded by an outline of the semiconductor layer 20 and a line inward away therefrom by a channel width or less of the channel body has an impurity concentration greater than that of the rest region. In addition, in the TFT 10, it is preferred that the region facing the gate electrode 14 and bounded by an outline of the semiconductor layer 20 and a line inward away therefrom by a channel width or less of the channel body has an impurity concentration greater than that of the rest region.

As mentioned above, the bump tends to be shown in Vg-Id characteristics of an N-channel transistor. So, when the TFT 10 of the present Embodiment is an N-channel transistor, the generation of the bump can be effectively suppressed.

In the present Embodiment, the above-mentioned TFT 10 and a high withstand voltage TFT (a TFT that can be driven even at a high voltage) may be simultaneously formed. FIGS. 5(a) to 5(e) are cross-sectional views schematically showing other production steps of the semiconductor device in Embodiment 1.

In this case, as shown in FIG. 5 (a), the base layer 17, the island-shaped semiconductor layers 20a and 20b, and the first insulating film 12 are formed on the substrate 11 in this order by the above-mentioned method. Then, as shown in FIG. 5 (b), only the first insulating film 12 on the semiconductor layer 20a is patterned. Then, as shown in FIG. 5(c), the second insulating film 13 is formed over the entire substrate. Thus, the semiconductor layer 20b is covered with the first and second insulating films 12 and 13. As a result, an insulating film on the semiconductor layer 20b, having a thickness greater than that of an insulating layer on the semiconductor layer 20a, is provided.

Then, as shown in FIG. 5(d), channel doping, formation of the gate electrode 14, and heavy doping for source-drain are performed by the above-mentioned method. Thus, the channel region 21 and the source-drain regions 22 are formed in the semiconductors layers 20a and 20b.

Then, as shown in FIG. 5(e), formation of the interlayer insulating film 15, hydrogenating and activating the semiconductor layers 20a and 20b, and formation of the wirings 16a and 16b are performed by the above-mentioned method. Thus, a TFT 10b can be formed easily and simultaneously with a TFT 10a having the same semiconductor layer 20a similarly to the above-mentioned TFT 10. The TFT 10b including an insulating film with a large thickness and an excellent breakdown withstand voltage is preferred as a TFT driven at a high voltage, such as 10V or more (a high-voltage transistor). In the TFT 10a, an insulating film on the channel region, that is, on the non-edge portion (inside portion) of the semiconductor layer 20a facing the gate electrode 14 is constituted by only the first insulating film 12, thereby providing the insulating film having a small thickness. Accordingly, the TFT 10a is preferred as a TFT driven at a low voltage, such as 5 V or less (a low-voltage transistor).

FIGS. 6(a) and 6(b) are cross-sectional views schematically showing another production method of the semiconductor device in Embodiment 1.

In the present Embodiment, the first insulating film 12 may not be patterned, and instead, the insulating film 13 may be patterned to be left in the channel edge region. Specifically, the first and second insulating films 12 and 13 are successively formed in the semiconductor layer 20 as shown in FIG. 6(a), and then the second insulating film 13 in channel body region is removed as shown in FIG. 6(b). Thereby, the insulating film on the channel edge region has a thickness greater than that on the channel body region. Therefore, after this, the channel edge region having an impurity concentration greater than that of the channel body region can be provided by performing channel doping using the above-mentioned method.

In this case, it is preferred to increase an etch selectivity of a layer to be etched (the second insulating film 13) with respect to an etching stop layer (the first insulating film 12). Therefore, the second insulating film 13 and the first insulating film 12 are preferably made of different materials. By doing so, only such a second insulating film 13 can be effectively etched, while the first insulating film 12 is not unnecessarily etched. For example, when the first insulating film constituted by a SiO₂ film, a SiN film is preferable as the second insulating film 13 in view of the high etch selectivity.

In this case, the second insulating film 13 may serve as a covering film and also may serve as a sacrificial film that is removed after the channel doping. That is, after the channel doping, the second insulating film 13 may be removed, leaving the first insulating film 12. This permits that the material for the second insulating film 13 is more freely selected. Therefore, the etch selectivity of the second insulating film 13 with respect to the first insulating film 12 can be more easily increased. More specifically, when a SiO₂ film constitutes the first insulating film 12, films mentioned below, in addition to the inorganic insulating films such as a SiN film, may be used as the second insulating film 13 that also functions as a sacrificial film. Metal films such as a titanium (Ti) film, an aluminum (Al) film, and a tantalum (Ta) fill; films made of compounds of the corresponding metals; and organic films such as films made of photosensitive resins. As just described, the sacrificial film may be a conductive film or an organic film. In order to make the metal film, which is the sacrificial film, also serves as the covering film, the thickness of the metal film may be about 10 to about 100 nm (preferably 20 to 50 nm). In order to make the organic film, which is the sacrificial film, also serves as the covering film, the thickness of the organic film may be about 30 to about 300 nm (preferably 50 to 100 nm). The organic film may be an insulating film or a conductive film.

In the present Embodiment, the first and second insulating layers 12 and 13 may be a sacrificial film. That is, after performing the channel doping utilizing the difference of the thickness of the insulating layers as shown in FIG. 4 or 6, the first insulating layer 12 and the second insulating layer 13 are etched off by HF and the like. And then a desired insulating film may be newly formed, and then, the gate electrode-formation step and the subsequent steps may be performed to make the TFT 10.

FIG. 7 is across-sectional view schematically showing another production method of the semiconductor device in Embodiment 1.

In the present Embodiment, the second insulating film 13 may not be formed, and instead, the first insulating film 12 in the channel body region may be formed to have a small thickness. Specifically, by the above-mentioned methods, the semiconductor layer 20 is formed by patterning, the first insulating film 12 is formed, and a resist is then patterned in a region other than the channel body region. Then, the first insulating film 12 in the region other than the channel edge region is etched to have a small thickness using HF or the like as shown in FIG. 7. Thus, the first insulating film 12 includes an edge covering portion 12a and an inside covering portion 12b, the edge covering portion 12a having a large thickness and being a region corresponding to the channel edge region, the inside covering portion 12b having a small thickness and being a region corresponding to the channel body region. Then, channel doping is performed by the above-mentioned method to make the channel edge region having an impurity concentration greater than that of the channel body region.

FIG. 8 is a cross-sectional view schematically showing another production method of the semiconductor device in Embodiment 1.

In the present Embodiment, channel doping may be performed through a sacrificial film selectively formed on the channel edge region. Specifically, the semiconductor layer 20 is patterned by the above-mentioned methods, and a sacrificial film 23 is then formed by patterning in the channel edge region as shown in FIG. 8. And the channel edge region may be then doped with impurities through the sacrificial film 23, and simultaneously the channel body region may be directly doped with impurities.

FIGS. 9(a) to 9(c) are cross-sectional views schematically showing another production method of the semiconductor device in Embodiment 1.

In the present Embodiment, channel doping may be performed through an oxide film selectively formed in the channel edge region. First, a semiconductor layer 20 is patterned by the above-mentioned methods, and then the semiconductor layer 20 is thermally oxidized to form a thermal oxide film 24 having a thickness of about 10 to about 100 nm (preferably 30 to 70 nm) on the surface thereof as shown in FIG. 9(a). Then, as shown in FIG. 9(b), a SiN film 25 is formed by patterning in a region on the channel body region other than the channel edge region. Then, by LOCOS oxidation, a LOCOS oxide film 26 having a thickness of about 10 to about 100 nm (preferably 30 to 70 nm) is formed on the thermal oxide film 24 surface in the channel edge region where no SiN film 25 has been formed, as shown in FIG. 9(c). Then, after removing the SiN film 25, the channel edge region is doped with impurities through the LOCOS oxide film 26, and the channel body region is simultaneously doped with impurities through the thermal oxide film 24. In this case, a substrate resistant to a high temperature process, such as a quartz substrate, is preferably used as the substrate 11 because the thermal oxidation of the semiconductor layer 20 and the LOCOS oxidization are usually performed at extremely high temperatures, for example, not less than 1000° C.

The present invention is described in more detail below with reference to Examples, but not limited to these Embodiments.

### Example 1

FIG. 10 is a cross-sectional view schematically showing a configuration of the TFT in accordance with Example 1.

The TFT in accordance with Example 1 is made as follows. First, a base layer 37 made of SiO₂ and SiN with a thickness of 300 nm was formed on a glass substrate 31 by the above-mentioned method, and an island-shaped polysilicon layer 40 with a thickness of 50 nm was formed by patterning. Then, a SiO₂ film 32 with a thickness of 50 nm was formed, a resist was formed by patterning and the SiO₂ film 32 on a region other than the edge of the polysilicon layer 40 was etched off using HF, by photolithography. The SiO₂ film 32 was patterned to cover the polysilicon layer 40 in a region from an end thereof to the inside of the end by 0.5 μm as shown in FIG. 10. That is, the width of the channel edge was 0.5 μm. Then, a SiO₂ film 33 with a thickness of 30 μm was formed on the polysilicon layer 40 and the SiO₂ film 32. Then, the polysilicon layer 40 was doped with boron as an impurity through the SiO₂ film 32 and the SiO₂ film 33 at an acceleration voltage of 30 keV and at a dose amount of 1×10¹³ ion/cm² by ion doping.

The TFT of the present Example was made by performing the following steps in accordance with the above-mentioned method: formation of a gate electrode of tungsten (W) with a thickness of 400 nm; heavy doping for source-drain, formation of an interlayer insulating film of SiO₂ and SiNO with a thickness of 1 μm; hydrogenation and activation of a polysilicon layer; formation of a contact hole; and formation of a wiring made of aluminum (Al). The channel length and the channel width of the polysilicon layer 40 were 3.5 μm and 10 μm, respectively. Therefore, the width of the channel body region (width in a channel width direction) of the polysilicon layer 40 was 9 μm.

### Comparative Example 1

A TFT in accordance with Comparative Example 1 was formed in a manner similar to Example 1, except that no SiO₂ film 32 was formed. In this way, the TFT of Comparative Example 1 had a structure where a single-layered SiO₂ film 33 was formed on the polysilicon layer 40.

### Vg-Id Characteristics

FIG. 11 is a graph showing Vg-Id characteristics of the TFTs in accordance with Example 1 and Comparative Example 1. FIG. 11(a) shows those in a saturation region. FIG. 11(b) shows those in a linear region. The Vg-Id characteristics in a saturation region were measured at a source-drain voltage Vds of 5 V. Those in a linear region were measured at a source-drain voltage Vds of 0.1 V.

As shown in FIG. 11, the both Vg-Id curves of the TFT in Comparative Example 1, which is the conventional TFT, in the linear region and the saturation region, had a bump. In contrast thereto, the Vg-Id curves of the TFT in Example 1, in the linear region and the saturation region, had no bump.

The present application claims priority to Patent Application No. 2007-241052 filed in Japan on Sep. 18, 2007 under the Paris Convention and provisions of national law in a designated State, the entire contents of which are hereby incorporated by reference.

### BRIEF DESCRIPTION OF DRAWINGS

FIG. 1 is a schematic view showing a configuration of the semiconductor device in accordance with Embodiment 1. FIG. 1(a) is a plan view thereof. FIG. 1(b) is a sectional view taken along line Y1-Y2 in FIG. 1(a). FIG. 1(c) is a sectional view taken along line X1-X2 in FIG. 1(a).

FIG. 2 is a conceptual view showing gate voltage-drain current characteristics of the TFT in accordance with Embodiment 1.

FIGS. 3(a) and 3(b) are plan views schematically showing the semiconductor device in accordance with a modified example of Embodiment 1.

FIG. 4 is a cross-sectional view schematically showing a configuration of the semiconductor device in accordance with Embodiment 1 in the respective production steps.

FIGS. 5(a) to 5(e) are cross-sectional views schematically showing other production steps of the semiconductor device in Embodiment 1.

FIGS. 6(a) and 6(b) are cross-sectional views schematically showing another production method of the semiconductor device in Embodiment 1.

FIG. 7 is a cross-sectional view schematically showing another production method of the semiconductor device in Embodiment 1.

FIG. 8 is a cross-sectional view schematically showing another production method of the semiconductor device in Embodiment 1.

FIGS. 9(a) to 9(c) are cross-sectional views schematically showing another production method of the semiconductor device in Embodiment 1.

FIG. 10 is a cross-sectional view schematically showing a configuration of the TFT in accordance with Example 1.

FIG. 11 is a graph showing Vg-Id characteristics of the TFTs in accordance with Example 1 and Comparative Example 1. FIG. 11(a) shows those in a saturation region. FIG. 11(b) shows those in a linear region.

FIG. 12 is a schematic view showing a configuration of the conventional TFT. FIG. 12(a) is a plan view thereof. FIG. 12(b) is a sectional view taken along line Y3-Y4 in FIG. 12(a). FIG. 12(c) is a sectional view taken along line X3-X4 in FIG. 12(a).

FIG. 13 is a conceptual view showing gate voltage-drain current characteristics of the conventional TFT.

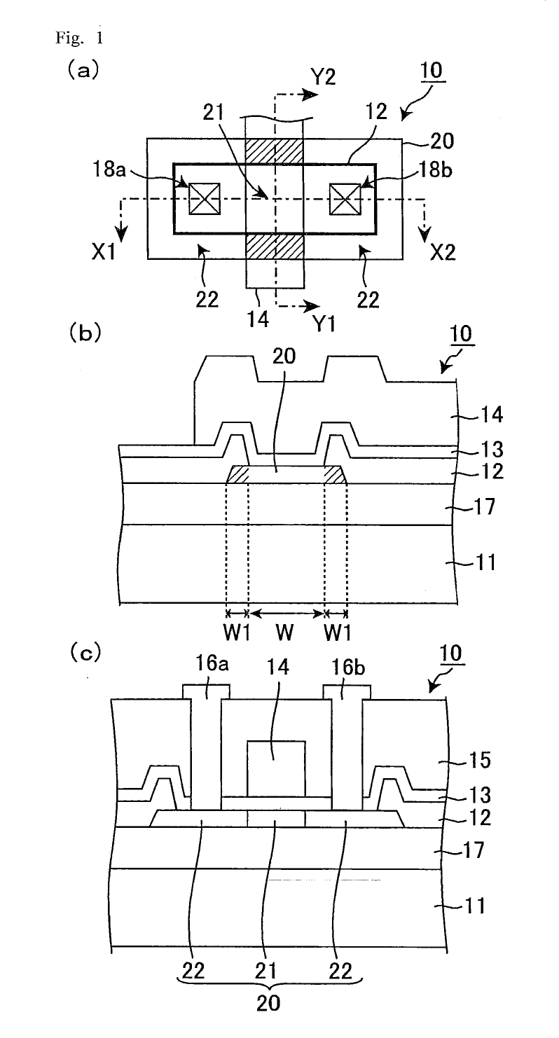

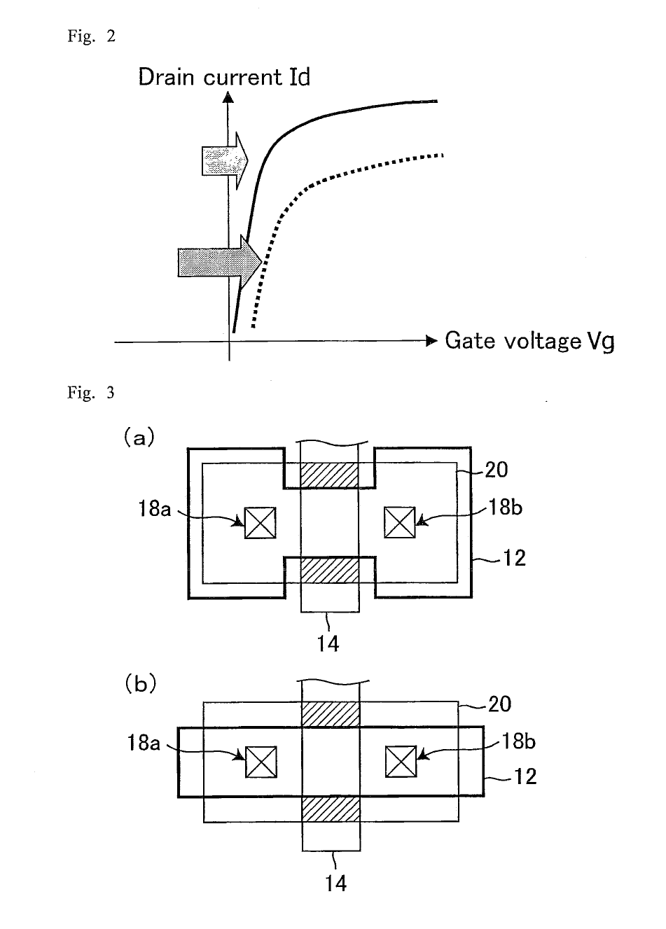

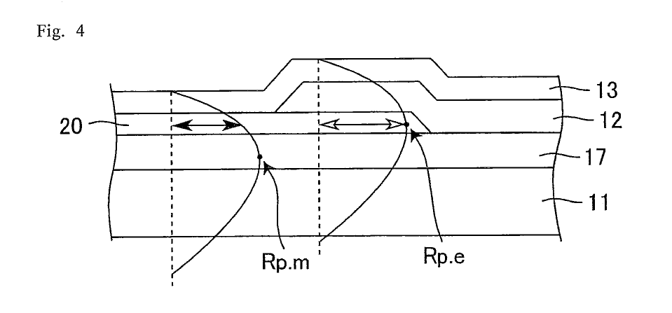

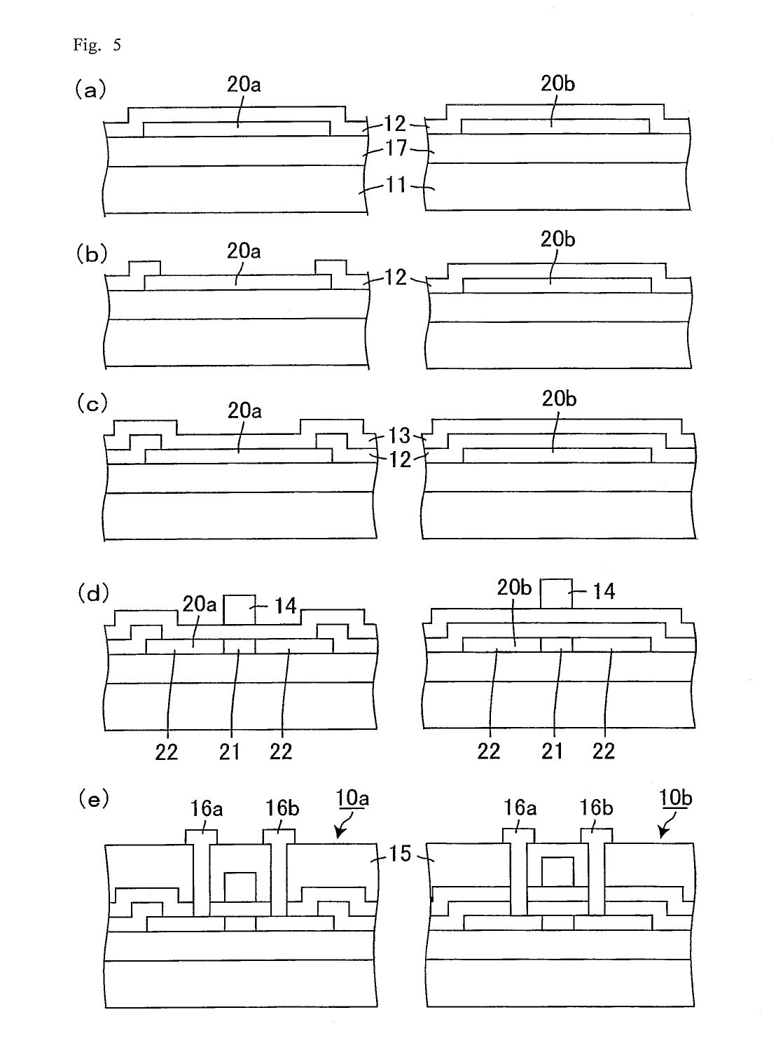

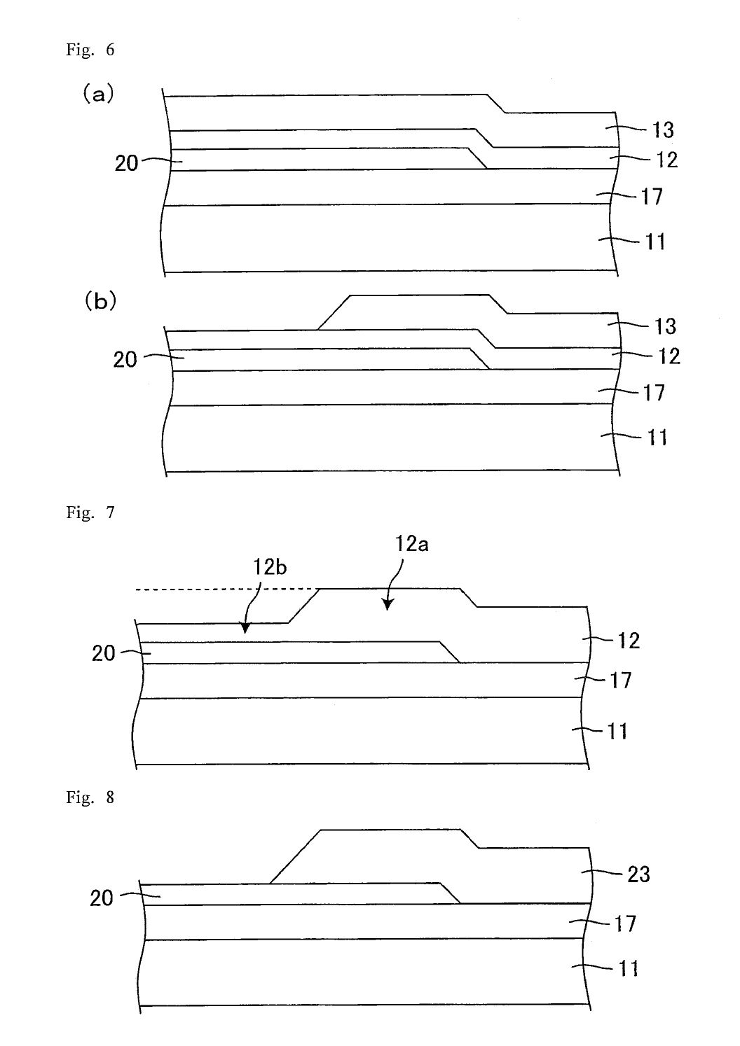

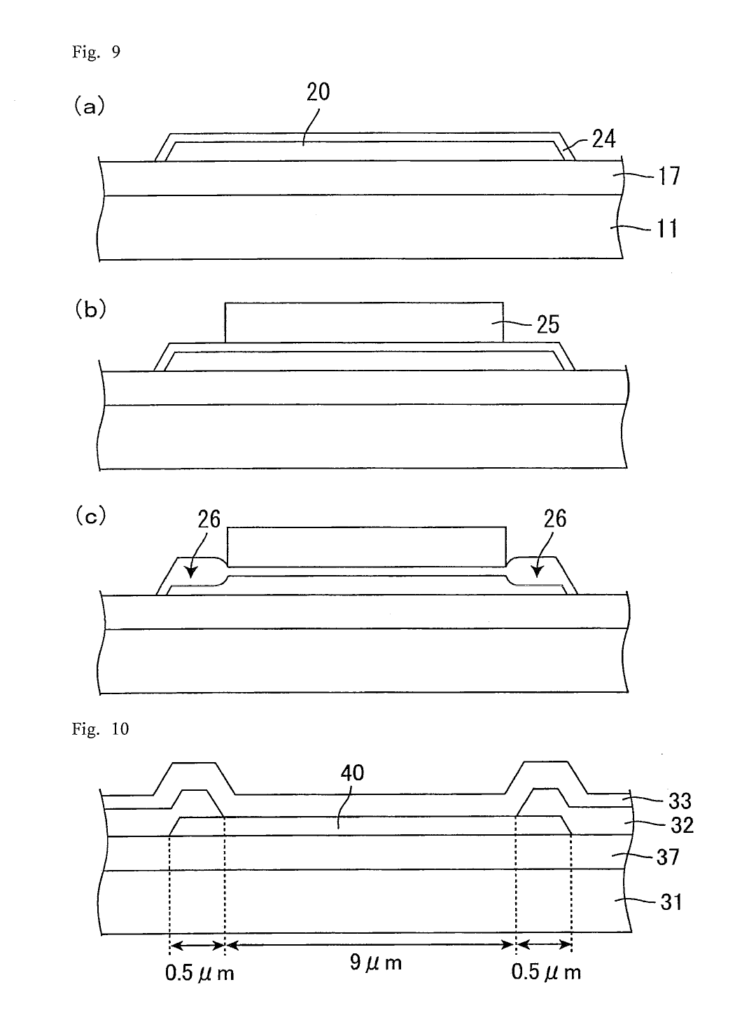

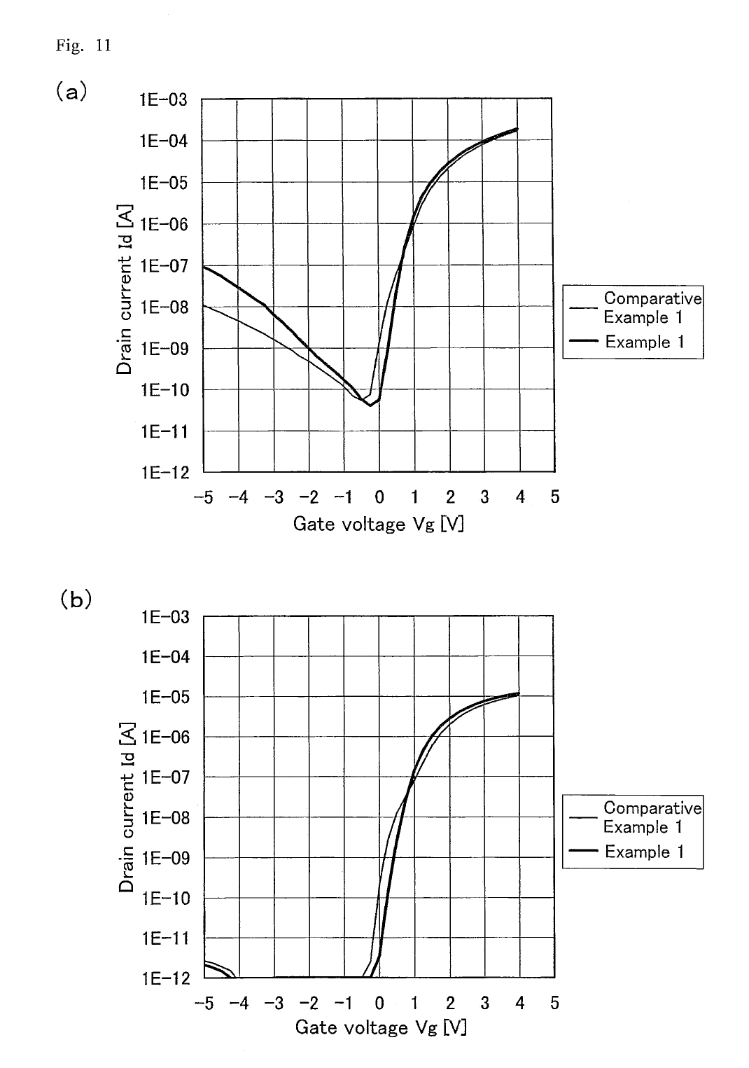

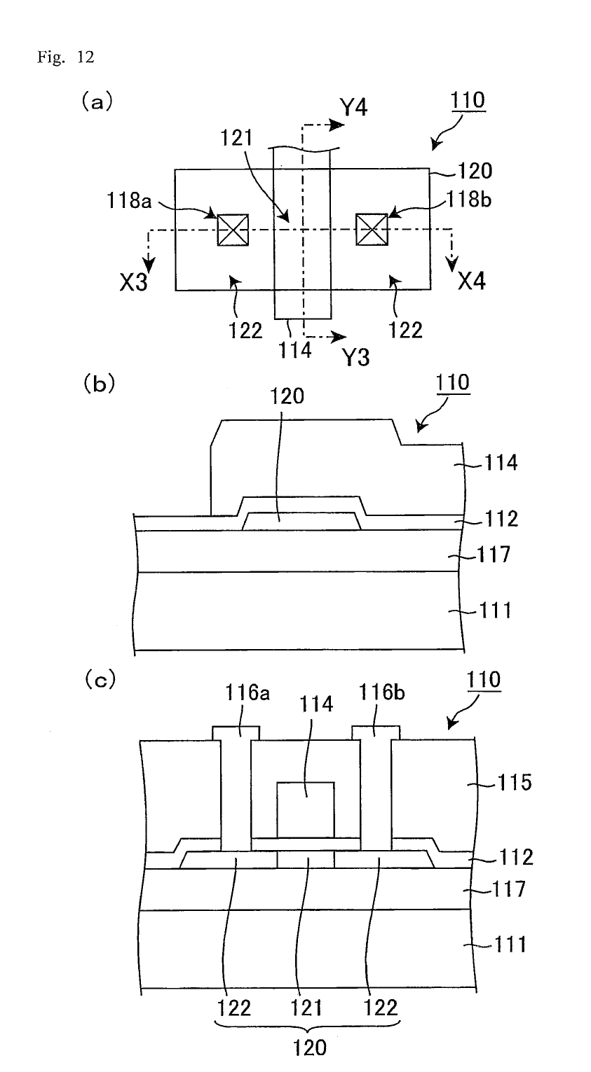

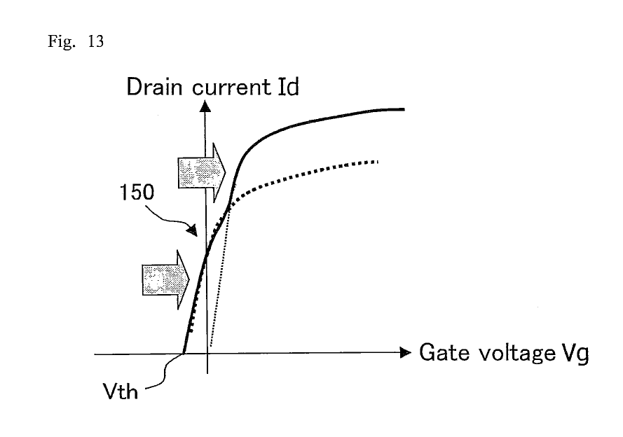

### EXPLANATION OF NUMERALS AND SYMBOLS

10, 10a, 10b, 110: Thin film transistor (TFT)
11, 111: Substrate
12: First insulating film
12a: Edge-covering portion
12b: Inside-covering portion
13: Second insulating film
14, 114: Gate electrode
15, 115: Interlayer insulating film
16a, 16b, 116a, 116b: Wiring
17, 117: Base layer (base coat layer)
18a, 18b: Contact hole
20, 20a, 20b, 120: Semiconductor layer
21, 121: Channel region
22, 122: Source-drain region (heavily impurity-doped region)
23: Sacrificial film
24: Thermal oxide film
25: SiN film
26: LOCOS oxide film
10, 10a, 10b, 110: Thin film transistor (TFT)
31: Glass substrate
32, 33: SiO₂ film
37: Base layer
40: Polysilicon layer
112: First insulating film
150: Bump (shoulder)
Rp,e: Peak of impurity concentration in channel edge region
Rp,m: Peak of impurity concentration in channel body region
Vth: Threshold voltage

1. A production method of a semiconductor device including a structure in which a semiconductor layer, an insulating film, and a gate electrode are stacked on a main surface of a substrate in this order,
the method comprising an impurity-adding step of:
adding impurities to at least a portion of the semiconductor layer, the portion facing the gate electrode, so that a portion of the semiconductor layer, the portion being an edge region and facing the gate electrode, has an impurity concentration greater than an impurity concentration of a portion of the semiconductor layer, the portion being a non-edge region and facing the gate electrode.

2. The production method of the semiconductor device according to claim 1,
wherein the impurity-adding step is performed so that a depth profile of the impurity concentration in the portion of the semiconductor layer, the portion being a non-edge region and facing the gate electrode, has a peak at a position deeper than a position of a peak of a depth profile of the impurity concentration in the portion of the semiconductor layer, the portion being an edge region and facing the gate electrode.

3. The production method of the semiconductor device according to claim 1,
wherein in the impurity-adding step, the impurities are added through a covering film covering the portion of the semiconductor layer, the portion facing the gate electrode,
the covering film includes an edge-covering portion and an inside-covering portion,
the edge-covering portion covering the portion of the semiconductor layer, the portion being an edge region and facing the gate electrode,
the inside-covering portion covering the portion of the semiconductor layer, the portion being a non-edge region and facing the gate electrode,
the edge-covering portion having a thickness greater than a thickness of the inside-covering portion.

4. The production method of the semiconductor device according to claim 3,
wherein the covering film is a multi-layer film including an edge-covering film and a channel-covering film,
the edge-covering film covering the portion of the semiconductor layer, the portion being an edge region and facing the gate electrode,
the channel-covering film covering the portion of the semiconductor layer, the portion facing the gate electrode.

5. The production method of the semiconductor device according to claim 4,
wherein the edge-covering film is made of a material different from a material for the channel-covering film.

6. The production method of the semiconductor device according to claim 4,
wherein the edge-covering film is a sacrificial film removed after the impurity-adding step.

7. The production method of the semiconductor device according to claim 4,
wherein the edge-covering film and the channel-covering film are inorganic insulating films.

8. The production method of the semiconductor device according to claim 3,
wherein the covering film is a single layered-film.

9. The production method of the semiconductor device according to claim 8,
wherein the edge-covering portion and the inside-covering portion are an inorganic insulating film.

10. The production method of the semiconductor device according to claim 1,
wherein in the impurity-adding step, the impurities are added to the portion of the semiconductor layer, the portion being an edge region and facing the gate electrode, through a covering film and simultaneously,
the impurities are directly added to the portion of the semiconductor layer, the portion being a non-edge region and facing the gate electrode,
the covering film covering the portion of the semiconductor layer, the portion being an edge region and facing the gate electrode,
the portion of the semiconductor layer, the portion being a non-edge region and facing the gate electrode, being exposed.

11. The production method of the semiconductor device according to claim 10,
wherein the covering film is an inorganic insulating film.

12. The production method of the semiconductor device according to claim 10,
wherein the covering film is a sacrificial film removed after the impurity-adding step.

13. The production method of the semiconductor device according to claim 1,
further comprising a step of selectively oxidizing a surface of the portion of the semiconductor layer, the portion being an edge region and facing the gate electrode, thereby forming an oxide film thereon,
wherein in the impurity-adding step, the impurities are added to the portion of the semiconductor layer, the portion being an edge region and facing the gate electrode, through the oxide film, and
the impurities are directly added to the portion of the semiconductor layer, the portion being a non-edge region and facing the gate electrode.

14. The production method of the semiconductor device according to claim 3,
wherein the impurity-adding step is performed so that a depth profile of the impurity concentration in the portion of the semiconductor layer, the portion being an edge region and facing the gate electrode, has a peak at a position deeper than the semiconductor layer.

15. The production method of the semiconductor device according to claim 1,
wherein the semiconductor layer has an edge having a forward tapered cross section, and
the portion of the semiconductor layer, the portion being an edge region and facing the gate electrode, is a tapered portion with a thickness smaller than a thickness of a non-edge inside portion of the semiconductor layer.

16. The production method of the semiconductor device according to claim 1,
wherein the semiconductor layer is formed by etching in a patterning step, and
the portion of the semiconductor layer, the portion being an edge region and facing the gate electrode, is a portion having a structural defect due to the etching in the patterning step.

17. The production method of the semiconductor device according to claim 1,
wherein the portion of the semiconductor layer, the portion being an edge region and facing the gate electrode, is a portion overlapping with a portion of the insulating film on the semiconductor layer, the portion of the insulating film having a thickness smaller than a thickness of the insulating film positioned on an non-edge inside portion of the semiconductor layer.

18. The production method of the semiconductor device according to claim 1,
wherein the portion of the semiconductor layer, the portion being an edge region and facing the gate electrode, is a portion overlapping with a portion of the insulating film on the semiconductor layer, the portion of the insulating film having a structural defect much more than a portion of the insulating film positioned on an non-edge inside portion of the semiconductor layer has.

19. The production method of the semiconductor device according to claim 1,
wherein the impurities are added to at least the portion of the semiconductor layer, the portion facing the gate electrode, so that a region facing the gate electrode and bounded by an outline of the semiconductor layer and a line 0.1 μm or more inward away therefrom has an impurity concentration greater than an impurity concentration of the rest region

20. A semiconductor device comprising:
a structure in which a semiconductor layer, an insulating film, and a gate electrode are stacked on a main surface of a substrate in this order,
wherein the semiconductor device has a portion of the semiconductor layer, the portion being an edge region and facing the gate electrode, having an impurity concentration greater than an impurity concentration of a portion of the semiconductor layer, the portion being a non-edge region and facing the gate electrode.

21. The semiconductor device according to claim 20,
wherein a peak of a depth profile of the impurity concentration in the portion of the semiconductor layer, the portion being a non-edge region and facing the gate electrode, is at a position deeper than a position of a peak of a depth profile of the impurity concentration in the portion of the semiconductor layer, the portion being an edge region and facing the gate electrode.

22. The semiconductor device according to claim 20,
wherein the insulating film is a multi-layer film including an edge insulating film and a channel insulating film, the edge insulating film covering the portion of the semiconductor layer, the portion being an edge region and facing the gate electrode, the channel insulating film covering the portion of the semiconductor layer, the portion facing the gate electrode.

23. The semiconductor device according to claim 22,
wherein the edge insulating film is made of a material different from a material for the channel insulating film.

24. The semiconductor device according to claim 22,
wherein the edge insulating film and the channel insulating film are inorganic insulating films.

25. The semiconductor device according to claim 20,
wherein the insulating film includes an edge-covering portion and an inside-covering portion, the edge-covering portion covering the portion of the semiconductor layer, the portion being an edge region and facing the gate electrode, the inside-covering portion covering the portion of the semiconductor layer, the portion being a non-edge region and facing the gate electrode, the edge-covering portion and the inside-covering portion being different in thickness.

26. The semiconductor device according to claim 25,
wherein the edge-covering portion and the inside-covering portion are an inorganic insulating film.

27. The semiconductor device according to claim 20,
comprising an oxide film on a gate electrode side-surface of the portion of the semiconductor layer, the portion being an edge region and facing the gate electrode.

28. The semiconductor device according to claim 20,
wherein the semiconductor layer has an edge having a forward tapered cross section,
the portion of the semiconductor layer, the portion being an edge region and facing the gate electrode, is a tapered portion with a thickness smaller than a thickness of a non-edge inside portion of the semiconductor layer.

29. The semiconductor device according to claim 1,
wherein the semiconductor layer is formed by etching in a patterning step, and
the portion of the semiconductor layer, the portion being an edge region and facing the gate electrode, is a portion having a structural defect due to the etching in the patterning step.

30. The semiconductor device according to claim 20,
wherein the portion of the semiconductor layer, the portion being an edge region and facing the gate electrode, is a portion overlapping with a portion of the insulating film on the semiconductor layer, the portion of the insulating film having a thickness smaller than a thickness of the insulating film positioned on a non-edge inside portion of the semiconductor layer.

31. The semiconductor device according to claim 20,
wherein the portion of the semiconductor layer, the portion being an edge region and facing the gate electrode, is a portion overlapping with a portion of the insulating film on the semiconductor layer, the portion of the insulating film having a structural defect much more than a portion of the insulating film positioned on a non-edge inside portion of the semiconductor layer has.

32. The semiconductor device according to claim 20,
wherein the portion of the semiconductor layer, the portion being an edge region and facing the gate electrode, is a region bounded by an outline of the semiconductor layer and a line 0.1 μm or more inward away therefrom and facing the gate electrode.

33. A semiconductor device comprising:
a structure in which a semiconductor layer, an insulating film, and a gate electrode are stacked on a main surface of a substrate in this order,
wherein the semiconductor layer has a portion of the semiconductor layer, the portion being an edge region and facing the gate electrode, having a sheet resistance lower than a sheet resistance of a portion of the semiconductor layer, the portion being a non-edge region and facing the gate electrode.

34. A semiconductor device comprising:
a structure in which a semiconductor layer, an insulating film, and a gate electrode are stacked on a main surface of a substrate in this order,
wherein the semiconductor device includes an N-channel transistor and/or a P-channel transistor, the N-channel transistor satisfying the following formula (X), the P-channel transistor satisfying the following formula (Y):
Vth,e>Vth,m (X)
Vth,e<Vth,m (Y)
wherein in the formulae (X) and (Y), Vth,e represents a threshold voltage of transistor characteristics of a portion of the semiconductor layer, the portion being an edge region and facing the gate electrode, and Vth,m represents a threshold voltage of transistor characteristics of a portion of the semiconductor layer, the portion being a non-edge region and facing the gate electrode.
